(19) United States
(12) Patent Application Publication
(10) Pub. No.: US 2011/0239098 A1
(43) Pub. Date: Sep. 29, 2011

(54) Detecting Data Error

(75) Inventor: Timothy Perrin Fisher-Jeffes, Cambridge, MA (US)

(73) Assignee: MediaTek Singapore Pte. Ltd., Singapore (SG)

(21) Appl. No.: 12/732,682

(22) Filed: Mar. 26, 2010

(51) Int. Cl. H03M 13/09; G06F 11/10

(52) U.S. Cl. 714/807; 714/E11.032

(57) ABSTRACT

A method includes segmenting a first portion of a data block into a plurality of segments that includes a first segment. The data block includes a second portion, different from the first portion, which stores cyclic redundancy check data calculated from data stored in the first portion of the data block. The method also includes calculating cyclic redundancy check data from the first segment, and, translating the calculated cyclic redundancy check data to a location associated with the data block. The method also includes combining the cyclic redundancy check data associated with the first segment and cyclic redundancy check data associated with at least one other segment included in the plurality of segments. The method also includes using the combined cyclic redundancy check data for error detection.

### BACKGROUND

This description relates to a system and method for detecting errors in transmitted or stored data by using information embedded in the transmitted or stored data.

While providing vast amounts of data from one or more sources (e.g., transmission sites, storage devices), data transmission processes also exhibit risk in that the data may be modified in an unwanted manner. Noisy communication channels, damaged transmissions or storage media may cause such alternations in the transmitted data. To detect such errors, and possibly correct altered data, error-detecting and error-correcting techniques have been developed and refined. For example, a hash function may be implemented, in which a mathematical function converts a large amount of data into a smaller amount (e.g., a single integer) that is transmitted and provides a reference for detecting modifications to the transmitted data. One such hash function is a cyclic redundancy check (CRC) and is used with binary systems such as digital networks and storage devices such as hard drives. Using such a non-secure hash function, a short, fixed-length binary sequence, known as the CRC code or just CRC, is calculated for each data message and is sent or stored with the message. Upon being received or read, the calculation is repeated for each data message and if the newly calculated CRC does not match the earlier calculated CRC (e.g., stored with the data message), the block is considered to contain a data error and corrective action may be taken such as rereading or requesting the message be resent.

### SUMMARY

In general, in one aspect, a method includes segmenting a first portion of a data block into a plurality of segments that includes a first segment. The data block includes a second portion, different from the first portion, which stores cyclic redundancy check data calculated from data stored in the first portion of the data block. The method also includes calculating cyclic redundancy check data from the first segment, and, translating the calculated cyclic redundancy check data to a location associated with the data block. The method also includes combining the cyclic redundancy check data associated with the first segment and cyclic redundancy check data associated with at least one other segment included in the plurality of segments. The method also includes using the combined cyclic redundancy check data for error detection.

Implementations may include one or more of the following features. The cyclic redundancy check data associated with at least one other segment may be translated to the location associated with the data block. Calculating the cyclic redundancy check data from the first segment may include forward direction, reverse direction and forward and reverse direction calculations. The calculated cyclic redundancy check data from the first segment may include a maximum length sequence. Calculating the cyclic redundancy check data from the first segment may include initiating calculations from a non-zero state. The cyclic redundancy check data stored in the second portion of the data block may be calculated prior to transmission of the data block.

In general, in one aspect, a computing device includes a memory that is configured to store instructions. The computing device also includes a processor configured to execute the instructions to perform a method that includes segmenting a first portion of a data block into a plurality of segments that includes a first segment. The data block includes a second portion, different from the first portion, which stores cyclic redundancy check data calculated from data stored in the first portion of the data block. The method also includes calculating cyclic redundancy check data from the first segment, and, translating the calculated cyclic redundancy check data to a location associated with the data block. The method also includes combining the cyclic redundancy check data associated with the first segment and cyclic redundancy check data associated with at least one other segment included in the plurality of segments. The method also includes using the combined cyclic redundancy check data for error detection.

Implementations may include one or more of the following features. The cyclic redundancy check data associated with at least one other segment may be translated to the location associated with the data block. Calculating the cyclic redundancy check data from the first segment may include forward direction, reverse direction and forward and reverse direction calculations. The calculated cyclic redundancy check data from the first segment may include a maximum length sequence. Calculating the cyclic redundancy check data from the first segment may include initiating calculations from a non-zero state. The cyclic redundancy check data stored in the second portion of the data block may be calculated prior to transmission of the data block.

In general, in one aspect, a computer program product tangibly embodied in an information carrier and comprising instructions that when executed by a processor perform a method includes segmenting a first portion of a data block into a plurality of segments that includes a first segment. The data block includes a second portion, different from the first portion, which stores cyclic redundancy check data calculated from data stored in the first portion of the data block. The method also includes calculating cyclic redundancy check data from the first segment, and, translating the calculated cyclic redundancy check data to a location associated with the data block. The method also includes combining the cyclic redundancy check data associated with the first segment and cyclic redundancy check data associated with at least one other segment included in the plurality of segments. The method also includes using the combined cyclic redundancy check data for error detection.

Implementations may include one or more of the following features. The cyclic redundancy check data associated with at least one other segment may be translated to the location associated with the data block. Calculating the cyclic redundancy check data from the first segment may include forward direction, reverse direction and forward and reverse direction calculations. The calculated cyclic redundancy check data from the first segment may include a maximum length sequence. Calculating the cyclic redundancy check data from the first segment may include initiating calculations from a non-zero state. The cyclic redundancy check data stored in the second portion of the data block may be calculated prior to transmission of the data block.

These and other aspects and features and various combinations of them may be expressed as methods, apparatus, systems, means for performing functions, program products, and in other ways.

Other features and advantages will be apparent from the description in the claims.

### DESCRIPTION OF DRAWINGS

FIG. 1 illustrates processing payloads of data blocks.

FIG. 2 illustrates processing segments of data block payloads.

FIG. 3 illustrates block diagrams of CRC checkers.

FIG. 4 illustrates operations for processing data block payload segments.

FIG. 5 is a diagrammatic view of computing devices that execute a CRC checker.

FIGS. 6 and 7 are flowcharts of operations of a CRC checker.

### DETAILED DESCRIPTION

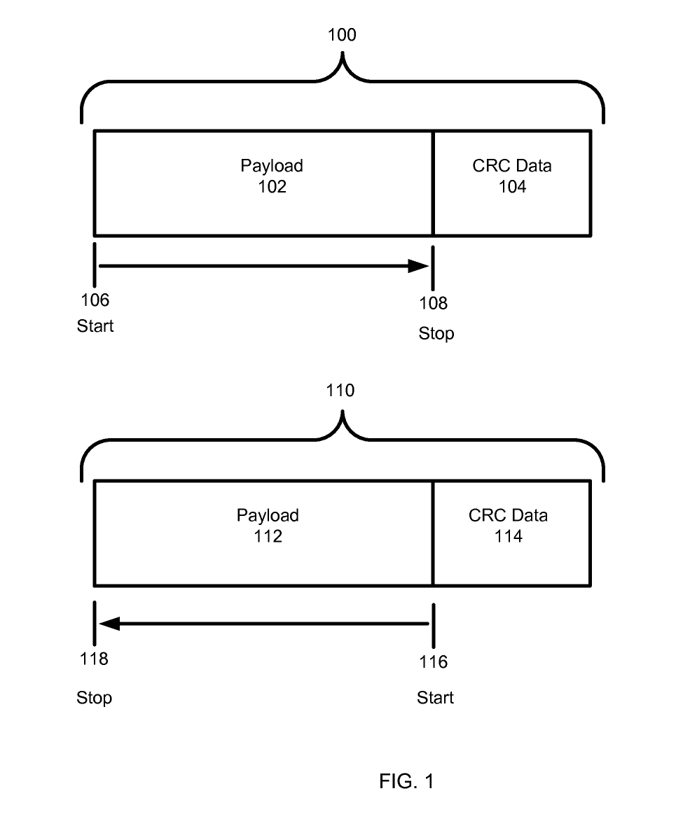

Referring to FIG. 1, an exemplary block of data 100 that may be received from various sources. For example, the data block 100 may be prepared and transmitted over one or more types of communication channels (e.g., a wireless channel) or retrieved from a storage device (e.g., a hard drive). Parameters and characteristics associated with the data block, such as length of the data block, information stored in the data block, etc., may depend upon the source of the data and the mode of transmission that the block is provided. In regards to error detection, two portions of the data block 100 are highlighted. In particular, a payload portion 102 of the data block 100 contain the data of interest that is being transported (e.g., over a wireless channel, from a hard drive, etc.). The data block 100 also includes a portion that contains data for detecting errors in the payload data (and possibly correcting the errors). In this particular example, CRC data 104 is contained in the data block 100 and is used to determine if one or more errors have been introduced into the payload 102 during transmission (or retrieval). To identify the potential error or errors, the CRC calculation used to generate the CRC data 104 (prior to being inserted in the data block 100) is repeated at the receiving end and the result of the calculation is compared to the CRC data stored in the data block. If the calculated data matches the CRC data 104 embedded in the data block 100, the information contains in the payload 102 may be considered error free. Alternatively, a non-match between the calculated CRC and the stored CRC data 104 may be indicative of one or more errors.

One or more techniques may be implemented for checking the CRC data 104 included in the data block 100 and the CRC data calculated from the payload 102 (upon receipt of the data block). For example, data may be accessed from the payload 102 in a particular manner for calculating the CRC (that is compared to the CRC data 104). In this particular example, data is read from one position 106 (i.e., the left most position), referred to as the start position, and progresses to a second position 108 (i.e., the right most position), referred to as the stop position. Moving from the start position 106 to the stop position 108, for reference, the data accessing direction is defined as being forward. As such, payload data is considered as being gathered in a forward direction for calculating the CRC. Alternatively, the opposite direction (e.g., backward direction) may also be used for gather payload data. Referring to exemplary data block 110, which includes a payload 112 and CRC data 114, data is accessed in the opposite direction. In particular, data is accessed from a start position 116 to a stop position 118 in a backward direction (compared to the forward direction associated with accessing the data of the data block 100). As such, CRC checking may be accomplished in either direction, forward or backward. The calculations and comparisons associated with CRC checking, while progressing through payload data in either direction, may be completed in a relatively efficient manner. However, some decoders (e.g., Turbo decoders) operate by dividing data payloads into segments and separately decoding each individual segment. Such decoding schemes, which typically involve considerable recursive iterations (e.g., sixteen to twenty-four iterations for Turbo decoders), may need significant processing time and computational resources (e.g., twelve times the processing time needed for CRC checking). To improve processing efficiency for such decoders, less intense processing operations may be executed in concert with the time consuming decoding operations. For example, CRC checking may be accomplished by executing operations on individual segments. Once decoding is completed, the CRC data associated with each segment may be used in combination to calculate CRC data for the entire data block (and be compared to the CRC data stored in the data block). In another arrangement, upon detecting one or more errors in an individual segment during CRC checking, decoding operations may be halted or other steps executed (e.g., repeat processing on the segment) to address the error detection. Along with improving efficiency, performing such functions in parallel may reduce consumption of computational resources.

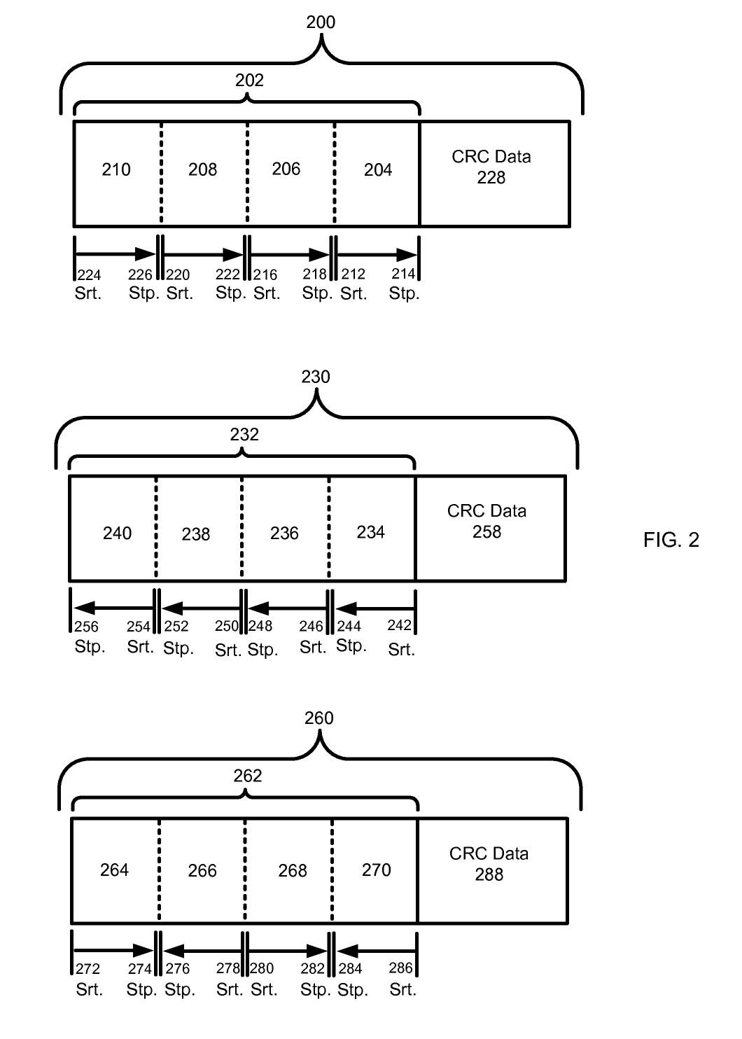

Referring to FIG. 2, an exemplary data block 200 includes a payload 202 that is divided into segments for decoding operations (e.g., Turbo decoding operations). For demonstrative purposes the payload 202 is divided into four segments 204, 206, 208, 210, however, for decoding operations such payloads may typically be divided into considerably more segments. To perform CRC checking for each segment, data is accessed from each segment using one or more directions. For this particular data block 200, data is accessed in the forward direction (as defined in FIG. 1) for each segment. For example, accessing is initiated from a starting point 212 and concludes at a stopping point 214 for segment 204. Moving forward, for the next segment 206, a starting point 216 defines the first data accessing point and stopping point 218 defines the concluding point for CRC checking for the segment. Similarly, starting points 220 and 224 and stopping points 222 and 226 respectively define the data locations for segments 208 and 210. Once attained, the CRC data (calculated from the segments) may be compared to CRC data 228 included in the data block 200 to determine if one or more errors has occurred (e.g., during transmission or retrieval).

Along with accessing segment data in a forward direction, a segmented payload may be accessed in a backward direction for CRC checking. For example, a payload 232 of a data block 230 may be divided in a manner similar to the payload of data block 200. As such, four demonstrative segments 234, 236, 238, 240 are each accessed in a backward direction. In particular, respective starting points 242, 246, 250, 254 and stopping points 244, 248, 252, 256 are used to access data for CRC checking of the payload segments 234, 236, 238, 240. To determine if one or more errors are present in the data, the calculated CRC data is compared to CRC data 258 included in the data block 230. For both data blocks 200, 230, each respective segment is accessed using the same direction, e.g., segments of data block 200 are accessed in a forward direction and segments of data block 230 are accessed in a backward direction. In some arrangements, accessing in different directions may be used for CRC checking of data block segments. For example, a payload 262 of a data block 260 may be divided into segments 264, 266, 268 and 270 that may be accessed in the forward or backward direction. In this example, segments 264 and 268 are accessed in the forward direction (e.g., defined by respective starting points 272, 280 and stopping points 274, 282) and segments 266 and 270 are accessed in the backward direction (e.g., defined by respective starting points 278, 286 and stopping points 276, 284). Similar to data blocks 200 and 230, the calculated CRC data from the segments is compared to CRC data 288 stored in the data block 260. In this particular example, an equivalent number of segments are accessed in the forward direction and in the backward direction (e.g., two segments for each direction). However, different numbers of segments may be accessed for each of the directions (e.g., more segments are accessed in the forward direction).

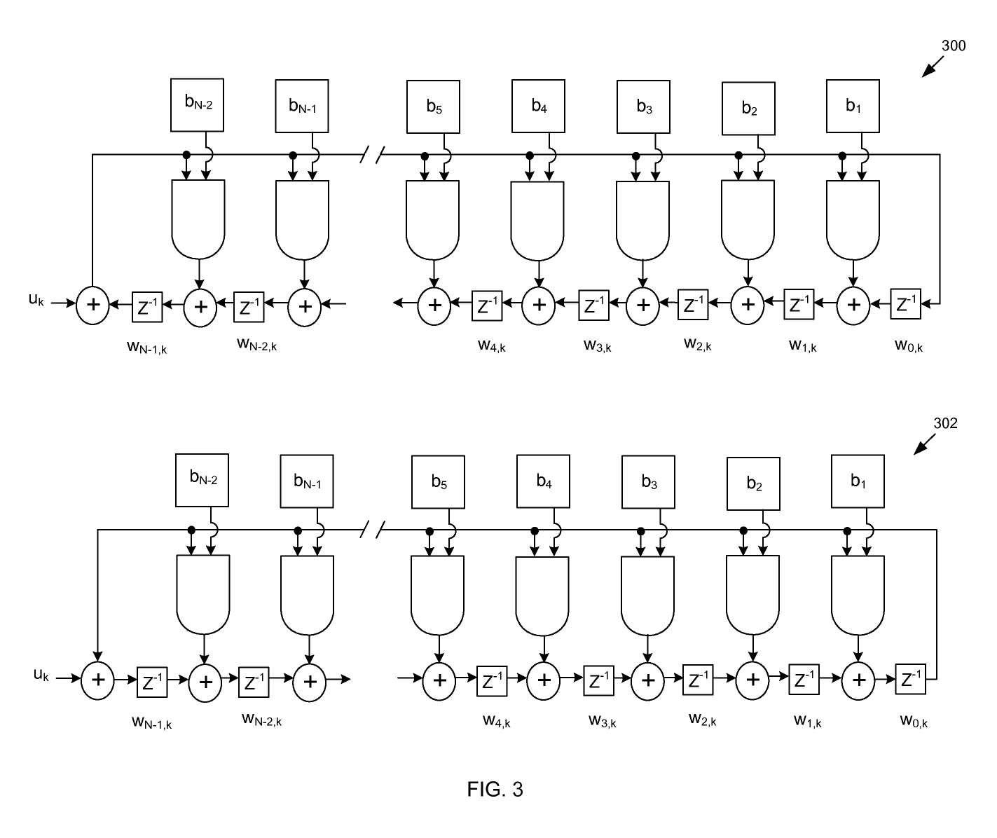

Referring to FIG. 3, to perform CRC checking from data included in a data block payload, one or more techniques may be implemented. For example, for CRC checking in the forward direction, a state-space may be represented as:

$$A = [ \begin{matrix}0 & 1 \\ I & b\end{matrix} ] , B = [ \begin{matrix}1 \\ b\end{matrix} ] ;$$

$${w}_{0} = {[ 0 … 0 ]}^{T} ;$$

$${w}_{k + 1} = A {w}_{k} ⊕ B {u}_{k} ; and$$

$$W = {w}_{k} .$$

In this representation, I is the identity matrix and b is a vector that represents a function used to generate the CRC data (e.g., polynomial tap positions excluding the first and last polynomial terms). The quantity wₖ, determined by modulo-2 addition, is the k-th CRC data vector and uₖ is the k-th bit of the data block payload. The quantity W represents the final value of the CRC word vector for the data block of length k.

Similarly, for CRC checking in the backward direction, the state space system is calculated from the inverse:

$$C = mod {2 [ \begin{matrix}0 & 1 \\ I & b\end{matrix} ]}^{- 1} ;$$

$$D = mod 2 [ \begin{matrix}C & ( \begin{matrix}1 \\ b\end{matrix} )\end{matrix} ] ;$$

$${w}_{k} = W ; and$$

$${w}_{k} = C {w}_{k + 1} ⊕ D {u}_{k} .$$

For matrices C and D, the matrix inverse operations are followed by a modulo-2 operation such that each matrix element has a value of “one” or “zero”. For the payload data to be considered as passing the CRC check, the vector w₀ includes all zero values.

Illustrated in the figure, a CRC checker 300 can access payload data in a forward direction to determine if CRC data calculated from the payload data matches CRC data extracted from the data block. Similarly, a CRC checker 302 is illustrated that operates in a reverse direction to determine if the CRC data matches. In both arrangements, uₖ represents the k-th bit of the payload data, and elements from the vector b (e.g., b₁, b₂, b₃, b₄, b₅, b_{N-2}, b_{N-1}, etc.) represent, for example, the terms of a polynomial (excluding the first and last polynomial term) selected to generate the CRC data. Similar addition operations (i.e., modulo-2 addition), logic operations (e.g., AND logical operations) and shift register operations (shift register elements are represented with Z⁻¹) are used in each arrangement. In general, CRC polynomials are often selected that have the property of being irreducible (e.g., cannot be factored into nontrivial polynomials over the same field). As such, temporarily ignoring the payload data input uₖ, the shift registers can be considered maximal length sequence generators. As such, the shift registers are capable of producing each possible binary sequence (before returning to the initial sequence) so long as the initial sequence is not a sequence of all zero values. While the CRC checkers 300, 302 are capable of checking entire data block payloads, such checkers architecture may be adjusted for checking payload segments.

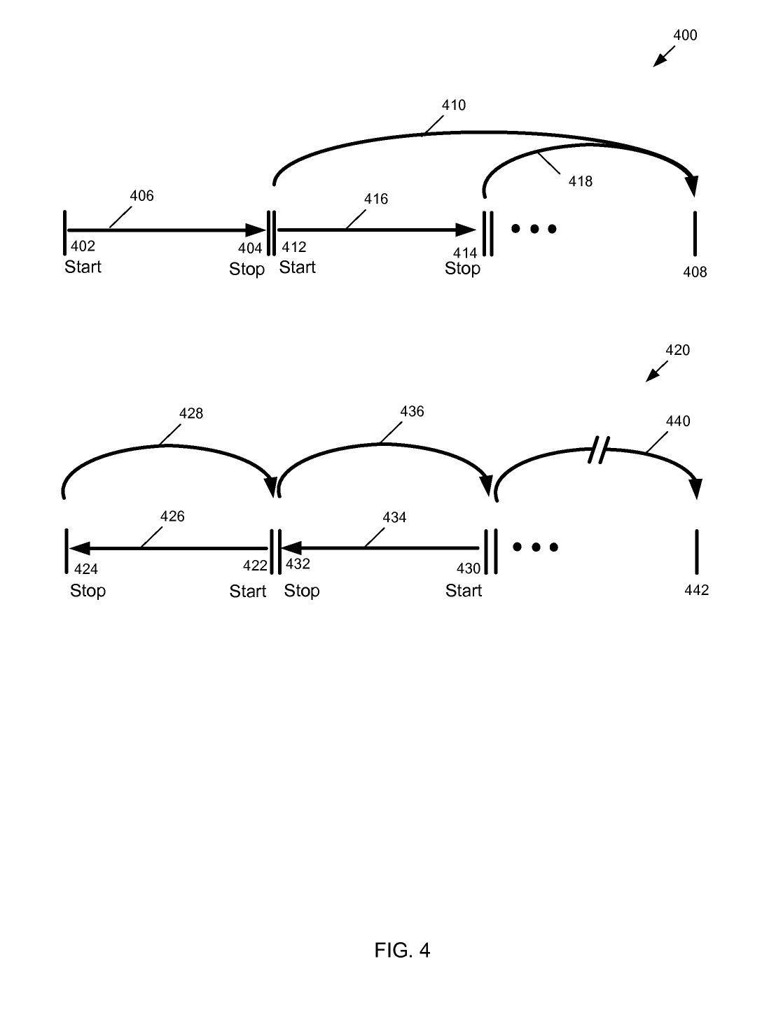

Referring to FIG. 4, one or more techniques may be used for CRC checking a segmented data block payload. For example, upon segmenting a payload, a CRC checking iteration may be performed on a segment and CRC data may be correspondingly produced. Similarly, CRC data may be produced for other segments included in the payload. To produce CRC data for the entire payload from the CRC data for each segment, the CRC data (for each segment) is translated to a common location and combined. For example, the CRC data may be translated to a location at one end of the payload and combined via modulo-2 addition. Once combined, this calculated CRC data may be used to determine if one or more errors has occurred in the data block payload (e.g., based upon transmission of the data block). For both forward and backward directions, such translating and combining of CRC data may provide CRC data for a data block payload.

In general, translation of the CRC data may be provided from a transform, E. For translating CRC data from a payload segment forward t steps, the transform may be represented as:

E=A^{t};

and for translating CRC data from a segment backward t steps, the transform may be represented as:

E=C^{t}.

For each segment, the initial value is the all zero state. For forward recursions, with a starting point S, a k-length CRC vector may be represented as:

wₛ=[0 . . . 0];

wₖ₊₁=A·wₖ⊕B·uₖ;

W=w_{S+t}.

Similarly, for backward recursions, with an ending point S, a t-length CRC vector may be represented as:

wₛ=[0 . . . 0];

wₖ=C·wₖ₊₁⊕D·uₖ;

Referring to FIG. 4, two W=w_{S-t}. exemplary techniques are graphically illustrated for translating CRC data associated with data block segments. In one example, represented with graphic 400, a data block payload is divided into a series of segments. For CRC checking, data is collected from the first segment in the forward direction from a starting point 402 to a stopping point 404 (as represented with an arrow 406). Upon reaching the stopping point 304, the CRC data associated with the segment is translated (e.g., using the E transform) to a location 408 at the end of the data block payload (as represented with an arrow 410). Stepping to the next payload segment, data is collected from a starting point 412 to a stopping point 414 (as represented with arrow 416), and CRC data associated with the segment is also translated to the location 408 (as represented with arrow 418). Progressing through the remaining payload segments (not shown), CRC data is similarly translated to the common location 408. Once translated, the CRC data associated with each payload segment may be combined (e.g., using modulo-2 addition) to aggregate the CRC data. The aggregate CRC data can then be used to determine if one or more errors are present in the data block payload. While the forward direction is used in this particular example, similar processing may also be executed in the opposite direction. Also, while this example sequentially processed segments in a serial manner in the forward direction, other processing patterns may also be implemented.

Graphical representation 420 illustrates another methodology for translating and combining CRC data associated with payload segments. In general, CRC data associated with two (or more) payload segments may be combined prior to being translated. Further, the combined CRC data may be translated to another payload segment and combined with additional CRC data (associated with the segment). Referring to the graphical representation 420, CRC data is calculated for a payload segment, translated to an adjacent segment and combined. For example, CRC data is calculated by progressing from a starting point 422 to a stopping point 424 associated with a payload segment (as represented with an arrow 426). Once calculated, the CRC data is translated to a location associated with an adjacent payload segment (as represented by an arrow 428). Similar to the first payload segment (defined by the starting point 422 and the stopping point 424), CRC data is also calculated for the adjacent segment by progressing from a starting point 430 to a stopping point 432 (as represented with an arrow 434). Upon reaching the stopping point 432, the calculated CRC data is combined (e.g., using modulo-2 addition) with the translated CRC data from the first segment. Once the CRC data from the two segments are combined, the aggregate CRC data is translated to a location associated with the next payload segment (as represented by an arrow 436). At this location, the aggregate CRC data is further combined with CRC data associated with the next payload segment and is translated. Such combining and translating of CRC data continues (as represented by an arrow 440) until reaching a location 442 associated with the last segment of the payload. Upon reaching this location, the translated and combined CRC data may be used to identify if one or more data errors are present in the payload of the data block.

In this particular example, CRC data is combined from two adjacent payload segments prior to being translated, however, other methodologies may also be implemented. For example, CRC data associated with more than two segments (e.g., three segments) may be combined and translated. Both forward and backward directions may be used for translating data along with translation positions for the CRC data associated with the payload segments. Further, while this example suggested that the payload segments have equivalent lengths, in some arrangement a variety of segment lengths may be implemented.

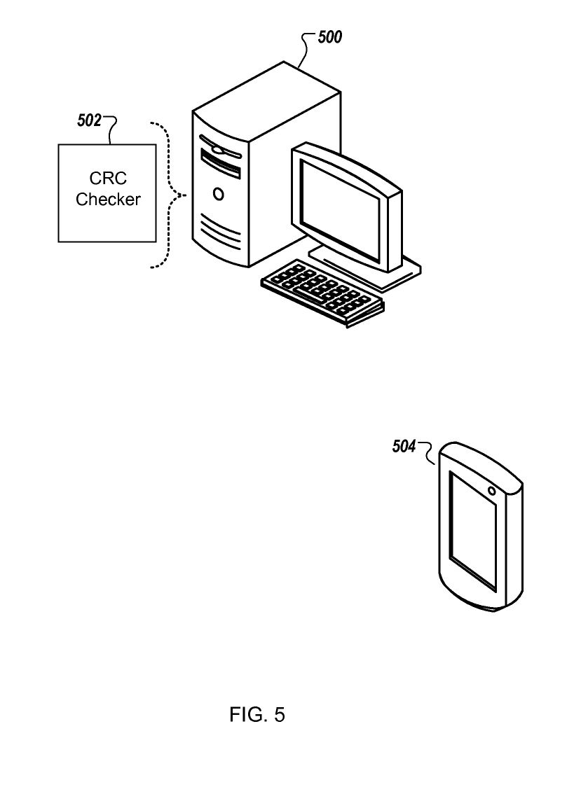

Referring to FIG. 5, one or more different types of computing devices and systems may be used for performing such CRC checking. For example a computer system 500 may include a CRC checker 502 that is capable of dividing data block payloads into segments for CRC checking. Along with producing the payload segments, the CRC checker 502 may also be capable of translating and combining CRC data to identify possible errors present in payload data. The CRC checker 502 may be implemented in one or more applications associated with the computer system, for example, detecting errors in data blocks provided from a storage device (e.g., a hard drive associated with the computer system), received from one or more transmissions (e.g., wired or wireless communications) and the like. Other types of computing devices may also execute the CRC checker 502, for example, a cellular telephone 504, a personal digital assistant, and other similar types of wireless devices. The CRC checker 502 may be implemented in software (e.g., as a function, process, application, or a collection thereof), hardware (e.g., circuitry) or a combination of hardware and software. While the CRC checker 502 is illustrated as being executed at a single computing device (e.g., the computer system 500), the functionality of the checker may be separate for distributed processing with multiple computing devices.

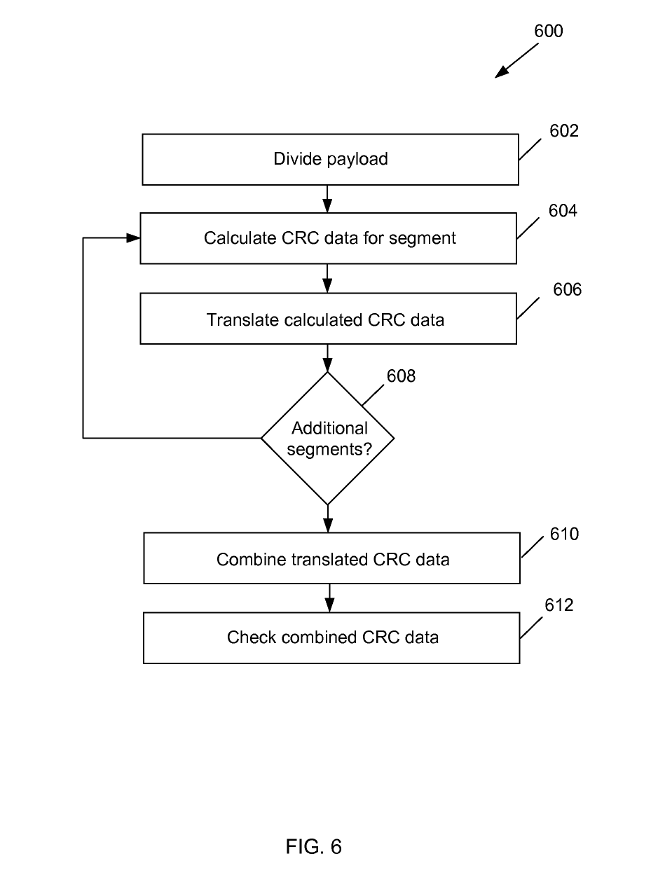

Referring to FIG. 6, a flowchart 600 represents some of the operations of a CRC checker such as the CRC checker 502 (shown in FIG. 5). Such a checker may be implemented in one or more types of hardware architectures such as a processor based architecture or other types of design. In some processor based architectures, the CRC checker may be executed on a single processor or distributed across multiple processors. Various types of circuitry (e.g., combinational logic, sequential logic, etc.) and computing devices (e.g., a computer system) may also be used individually or in combination to execute the operations of the CRC checker. For example, in a processor-based decoding system, instructions may be executed by a processor (e.g., a microprocessor) to provide the operations of the CRC checker. Such instructions may be stored in a storage device (e.g., hard drive, CD-ROM, etc.) and provided to the processor (or multiple processors) for execution.

Operations of the CRC checker include dividing 602 a payload of a data block or other type of data collection (e.g., retrieved from a storage device or received from one or more communications). Once segmented, the CRC checker may calculate 604 CRC data associated with a segment. In some arrangements, the CRC checker steps through the data segments in particular direction, such as a forward direction or a backward direction. Operations also include translating 606 the calculated CRC data, for example, the data calculated from the segment may be translated to a location associated with the data block payload (e.g., one end of the payload). Upon translating the data, operations may include determining 608 if additional payload segments need corresponding CRC data calculated and translated. If at least one additional payload segment is present, operations include returning to calculate 604 and translate 606 the appropriate CRC data. If CRC data has been calculated and translated for each payload segment, operations may include combining 610 the translated CRC data (e.g., translated to one end of the data block payload). Upon combining the data, the CRC checker may perform additional operations, for example, the combined data may be checked 612 to determine if one or more data errors have been detected by the checker. Such an operation may also be provided by another processing stage (e.g., after being provided the combined CRC data by the CRC checker).

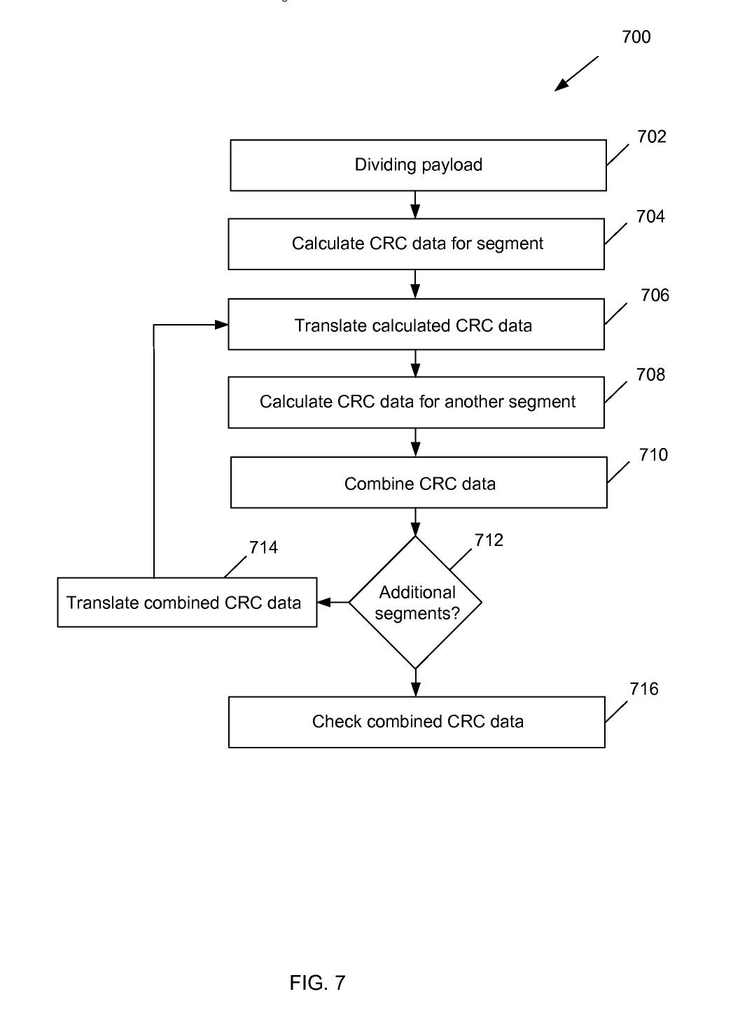

Referring to FIG. 7, a flowchart 700 represents another arrangement of operations of a CRC checker such as the CRC checker 502 (shown in FIG. 5). Similar to the CRC checker described with respect to flowchart 600 (shown in FIG. 6), such a checker may be implemented in one or more types of hardware architectures such as single or multiple processor based architectures. Similar to the flowchart 600, operations of the CRC checker include dividing 702 a data block into segments and calculating 704 CRC data for a segment. Such a calculation may be executed in a forward or backward direction. Once calculated, the CRC data is translated 706, for example, to a location e.g., associated with an adjacent payload segment. Operations also include calculating 708 CRC data for another payload segment, such as the adjacent segment (e.g., using the forward or backward direction). Once calculated, the CRC data associated with the first segment and the CRC data associated with the second segment are combined 710 (e.g., using modulo-2 addition). Upon combining the data, the CRC checker may determine 712 if additional payload segments are present and need to be checked. If at least one additional segment is present (e.g., an adjacent payload segment), the CRC checker translates 714 the combined CRC data (e.g., to a location associated with the adjacent payload segment) and returns to calculate 708 CRC data from the additional segment (and continues). If there are no additional segments, and the CRC checker has calculated CRC data from the payload segments, operations may include checking 716 the CRC data combined from the payload segments to determine if one or more errors in the payload data have been detected.

As mentioned above, CRC checking and operations associated with CRC checking (e.g., illustrated with flowcharts 600 and 700) may be executed by a computing device. For example a computing device may be a computer system that performs computer-implemented methods for executing instructions associated CRC checking of data blocks. The computing device may include a processor, a memory, a storage device, and an input/output device. Each of the components may be interconnected using a system bus or other similar structure. The processor may be capable of processing instructions for execution within the computing device. In one implementation, the processor is a single-threaded processor. In another implementation, the processor is a multi-threaded processor. The processor is capable of processing instructions stored in the memory or on the storage device to display graphical information for a user interface on the input/output device.

The memory stores information within the computing device. In one implementation, the memory is a computer-readable medium. In one implementation, the memory is a volatile memory unit. In another implementation, the memory is a non-volatile memory unit.

The storage device is capable of providing mass storage for the computing device. In one implementation, the storage device is a computer-readable medium. In various different implementations, the storage device may be a floppy disk device, a hard disk device, an optical disk device, or a tape device.

The input/output device provides input/output operations for the computing device. In one implementation, the input/output device includes a keyboard and/or pointing device. In another implementation, the input/output device includes a display unit for displaying graphical user interfaces.

The features described can be implemented in digital electronic circuitry, or in computer hardware, firmware, software, or in combinations of them. The apparatus can be implemented in a computer program product tangibly embodied in an information carrier, e.g., in a machine-readable storage device or in a propagated signal, for execution by a programmable processor; and method steps can be performed by a programmable processor executing a program of instructions to perform functions of the described implementations by operating on input data and generating output. The described features can be implemented advantageously in one or more computer programs that are executable on a programmable system including at least one programmable processor coupled to receive data and instructions from, and to transmit data and instructions to, a data storage system, at least one input device, and at least one output device. In some arrangements the operations associated with the instructions may be implemented in circuitry or other type of hardware. A computer program is a set of instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

Suitable processors for the execution of a program of instructions include, by way of example, both general and special purpose microprocessors, and the sole processor or one of multiple processors of any kind of computer. Generally, a processor will receive instructions and data from a read-only memory or a random access memory or both. The essential elements of a computer are a processor for executing instructions and one or more memories for storing instructions and data. Generally, a computer will also include, or be operatively coupled to communicate with, one or more mass storage devices for storing data files; such devices include magnetic disks, such as internal hard disks and removable disks; magneto-optical disks; and optical disks. Storage devices suitable for tangibly embodying computer program instructions and data include all forms of non-volatile memory, including by way of example semiconductor memory devices, such as EPROM, EEPROM, and flash memory devices; magnetic disks such as internal hard disks and removable disks; magneto-optical disks; and CD-ROM and DVD-ROM disks. The processor and the memory can be supplemented by, or incorporated in, ASICs (application-specific integrated circuits).

The features can be implemented in a computer system that includes a back-end component, such as a data server, or that includes a middleware component, such as an application server or an Internet server, or that includes a front-end component, such as a client computer having a graphical user interface or an Internet browser, or any combination of them. The components of the system can be connected by any form or medium of digital data communication such as a communication network. Examples of communication networks include, e.g., a LAN, a WAN, and the computers and networks forming the Internet.

The computer system can include clients and servers. A client and server are generally remote from each other and typically interact through a network, such as the described one. The relationship of client and server arises by virtue of computer programs running on the respective computers and having a client-server relationship to each other.

Other embodiments are within the scope of the following claims. The techniques described herein can be performed in a different order and still achieve desirable results.

What is claimed is:

1. A method comprising:
segmenting a first portion of a data block into a plurality of segments that includes a first segment, the data block includes a second portion, different from the first portion, which stores cyclic redundancy check data calculated from data stored in the first portion of the data block;
calculating cyclic redundancy check data from the first segment;
translating the calculated cyclic redundancy check data to a location associated with the data block;
combining the cyclic redundancy check data associated with the first segment and cyclic redundancy check data associated with at least one other segment included in the plurality of segments; and
using the combined cyclic redundancy check data for error detection.

2. The method of claim 1, wherein the cyclic redundancy check data associated with at least one other segment is translated to the location associated with the data block.

3. The method of claim 1, wherein calculating the cyclic redundancy check data from the first segment includes forward direction calculations.

4. The method of claim 1, wherein calculating the cyclic redundancy check data from the first segment includes reverse direction calculations.

5. The method of claim 1, wherein the calculated cyclic redundancy check data from the first segment includes a maximum length sequence.

6. The method of claim 1, wherein calculating the cyclic redundancy check data from the first segment includes initiating calculations from a non-zero state.

7. The method of claim 1, wherein the cyclic redundancy check data stored in the second portion of the data block is calculated prior to transmission of the data block.

8. A computing device comprising:
a memory configured to store instructions; and
a processor configured to execute the instructions to perform a method comprising:
segmenting a first portion of a data block into a plurality of segments that includes a first segment, the data block includes a second portion, different from the first portion, which stores cyclic redundancy check data calculated from data stored in the first portion of the data block;
calculating cyclic redundancy check data from the first segment;
translating the calculated cyclic redundancy check data to a location associated with the data block;
combining the cyclic redundancy check data associated with the first segment and cyclic redundancy check data associated with at least one other segment included in the plurality of segments; and
using the combined cyclic redundancy check data for error detection.

9. The computing device of claim 8, wherein the cyclic redundancy check data associated with at least one other segment is translated to the location associated with the data block.

10. The computing device of claim 8, wherein calculating the cyclic redundancy check data from the first segment includes forward direction calculations.

11. The computing device of claim 8, wherein calculating the cyclic redundancy check data from the first segment includes reverse direction calculations.

12. The computing device of claim 8, wherein the calculated cyclic redundancy check data from the first segment includes a maximum length sequence.

13. The computing device of claim 8, wherein calculating the cyclic redundancy check data from the first segment includes initiating calculations from a non-zero state.

14. The computing device of claim 8, wherein the cyclic redundancy check data stored in the second portion of the data block is calculated prior to transmission of the data block.

15. A computer program product tangibly embodied in an information carrier and comprising instructions that when executed by a processor perform a method comprising:
segmenting a first portion of a data block into a plurality of segments that includes a first segment, the data block includes a second portion, different from the first portion, which stores cyclic redundancy check data calculated from data stored in the first portion of the data block;
calculating cyclic redundancy check data from the first segment;
translating the calculated cyclic redundancy check data to a location associated with the data block;
combining the cyclic redundancy check data associated with the first segment and cyclic redundancy check data associated with at least one other segment included in the plurality of segments; and
using the combined cyclic redundancy check data for error detection.

16. The computer program product of claim 15, wherein the cyclic redundancy check data associated with at least one other segment is translated to the location associated with the data block.

17. The computer program product of claim 15, wherein calculating the cyclic redundancy check data from the first segment includes forward direction calculations.

18. The computer program product of claim 15, wherein calculating the cyclic redundancy check data from the first segment includes reverse direction calculations.

19. The computer program product of claim 15, wherein the calculated cyclic redundancy check data from the first segment includes a maximum length sequence.

20. The computer program product of claim 15, wherein calculating the cyclic redundancy check data from the first segment includes initiating calculations from a non-zero state.

21. The computer program product of claim 15, wherein the cyclic redundancy check data stored in the second portion of the data block is calculated prior to transmission of the data block.
